(19) United States
(12) Patent Application Publication
(10) Pub. No.: US 2013/0298978 A1
(43) Pub. Date: Nov. 14, 2013

(54) QUANTUM DOT SOLAR CELL

(71) Applicants: Zhi Zheng, Shanghai (CN); Anyuan Yin, Shanghai (CN); Anna Liu, Pudong New Area (CN); Marilyn Wang, Pudong New Area (CN); Linan Zhao, Pudong New Area (CN)

(72) Inventors: Zhi Zheng, Shanghai (CN); Anyuan Yin, Shanghai (CN); Anna Liu, Pudong New Area (CN); Marilyn Wang, Pudong New Area (CN); Linan Zhao, Pudong New Area (CN)

(73) Assignee: Honeywell International Inc., Morristown, NJ (US)

(21) Appl. No.: 13/980,352

(22) PCT Filed: Jan. 31, 2011
(86) PCT No.: PCT/CN11/00172

§ 371 Date: Jul. 18, 2013

(51) Int. Cl. H01L 51/42

(52) U.S. Cl. CPC H01L 51/4213
USPC 136/255; 438/82

(57) ABSTRACT

Solar cells with enhanced efficiency are disclosed. An example solar cell includes a first electrode (12). The first electrode (12) includes an electron conductor film (14). A quantum dot layer (16) is coupled to the electron conductor film (14). An electrolyte solution (18) is disposed adjacent to the quantum dot layer (16). A second electrode (20) is electrically coupled to one or more of the electrolyte solution (18) and the quantum dot layer (16). The second electrode (20) includes a sulfur-containing coating compound (24), and the electrolyte is a polysulfide electrolyte.

### TECHNICAL FIELD

The disclosure relates generally to solar cells, and more particularly to quantum dot solar cells.

### BACKGROUND

A wide variety of solar cells have been developed for converting sunlight into electricity. Of the known solar cells, each has certain advantages and disadvantages. There is an ongoing need to provide alternative solar cells as well as alternative methods for manufacturing solar cells.

### SUMMARY

The disclosure relates generally to solar cells. In some instances, a solar cell may include quantum dots as light sensitizers. An example solar cell may include an anode, a quantum dot layer electrically coupled to the anode, an electrolyte disposed adjacent to the quantum dot layer, and a sulfide cathode electrically coupled to one or more of the electrolyte and the quantum dot layer. In some instances, the electrolyte may be a polysulfide electrolyte, and the cathode may be a sulfide compound coated counter-electrode that is electrically coupled to a polysulfide electrolyte. The sulfide compound coated counter-electrode may include, for example, a coating material selected from the group comprising CuS, Cu₂S, CoS, CoS₂, and Fe₃S₄. However, these are just examples. While not required, the anode may include an electron conductor film, and in some cases, a mesoporous film having particles with an average particle size of between 10-300 nanometers. In some cases, the electron conductor film may include ZnO, TiO₂, or both.

An example method of manufacturing a solar cell may include providing an anode sometimes with an electron conductor film, depositing a quantum dot layer onto the electron conductor film, disposing a polysulfide electrolyte adjacent to the quantum dot layer, and electrically coupling a cathode to the polysulfide electrolyte, wherein the cathode may include a sulfur-containing compound.

The above summary is not intended to describe each and every disclosed embodiment or every implementation of the disclosure. The Figures and Description which follow more particularly exemplifies various examples.

### BRIEF DESCRIPTION OF THE FIGURE

The following description should be read with reference to the drawings. The drawings, which are not necessarily to scale, depict selected illustrative embodiments, and are not intended to limit the scope of the disclosure. The disclosure may be more completely understood in consideration of the following description of various embodiments in connection with the accompanying drawings, in which:

FIG. 1 is a schematic cross-sectional side view of an illustrative but non-limiting example of a solar cell;

FIG. 2 is a graph showing the 2p binding energy for Co plotted versus intensity;

FIG. 3 is a graph showing the 2p binding energy for S plotted versus intensity; and

FIG. 4 is a graph showing efficiency versus time for two illustrative solar cells.

While the disclosure is amenable to various modifications and alternative forms, specifics thereof have been shown by way of example in the drawing and will be described in detail. It should be understood, however, that the intention is not to limit the disclosure to the particular embodiments or examples described. On the contrary, the intention is to cover all modifications, equivalents, and alternatives falling within the spirit and scope of the disclosure.

### DESCRIPTION

The following description should be read with reference to the drawings in which similar elements in different drawings are numbered the same. The drawings, which are not necessarily to scale, depict certain illustrative embodiments and are not intended to limit the scope of the disclosure.

For the following defined terms, these definitions shall be applied, unless a different definition is given in the claims or elsewhere in this specification.

All numeric values are herein assumed to be modified by the term “about,” whether or not explicitly indicated. The term “about” generally refers to a range of numbers that one of skill in the art would consider equivalent to the recited value (i.e., having the same function or result). In many instances, the terms “about” may include numbers that are rounded to the nearest significant figure.

The recitation of numerical ranges by endpoints includes all numbers within that range (e.g. 1 to 5 includes 1, 1.5, 2, 2.75, 3, 3.80, 4, and 5).

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

The term “layer” as used herein should be read to include a layer of material even when a two or three-dimensional intermingling or interpenetration of the layer has occurred with an adjacent layer, unless the content clearly dictates otherwise.

A wide variety of solar cells (which also may be known as photovoltaics and/or photovoltaic cells) have been developed for converting sunlight into electricity. Some solar cells include a layer of crystalline silicon. Second and third generation solar cells often use a film of photovoltaic material (e.g., a “thin” film) deposited or otherwise provided on a substrate. These solar cells may be categorized according to the photovoltaic material used. For example, inorganic thin-film photovoltaics may include a thin film of amorphous silicon, microcrystalline silicon, CdS, CdTe, Cu₂S, copper indium diselenide (CIS), copper indium gallium diselenide (CIGS), etc. Organic thin-film photovoltaics may include a thin film of a polymer or polymers, bulk heterojunctions, ordered heterojunctions, a fullerence, a polymer/fullerence blend, photosynthetic materials, etc. These are only some examples.

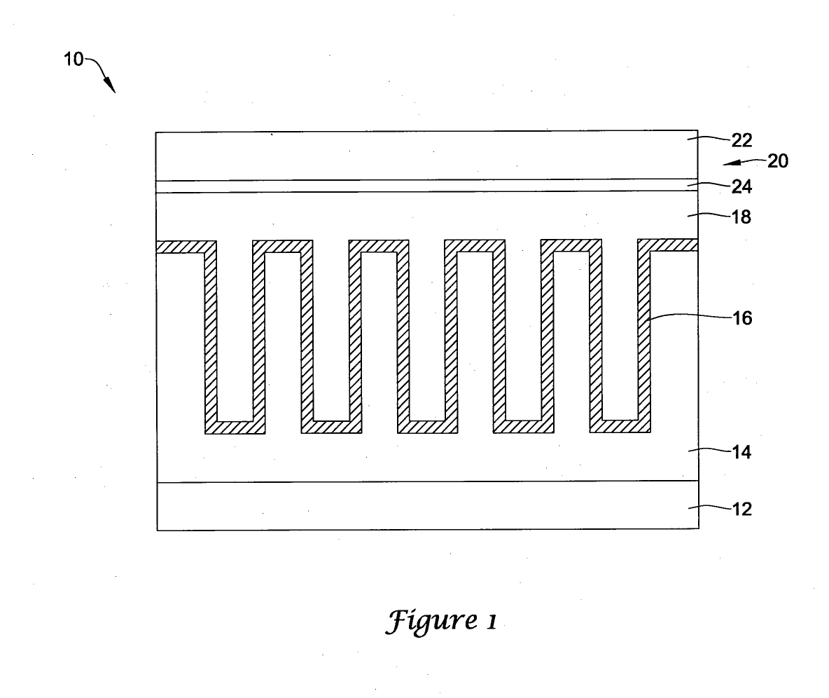

FIG. 1 is a schematic cross-sectional side view of an illustrative solar cell 10. In the illustrative embodiment, solar cell 10 includes a substrate or first electrode (e.g., an anode or negative electrode) 12. In some instances, electrode 12 may be termed an anode or a photo anode. An electron conductor layer 14 may be electrically coupled to, disposed on, or may actually form electrode 12. In some embodiments, electron conductor layer 14 may include or be formed to take the form of a structured pattern or array, such as a mesoporous film, a structured nanomaterials or other structured pattern or array, as desired. The structured nanomaterials may include clusters or arrays of nanospheres, nanotubes, nanorods, nanowires, nano inverse opals or any other suitable nanomaterials, as desired. In some cases, a mesoporous film may be formed that includes particles with an average particle size of between 10-300 nanometers, but this is not required. In some cases, the mesoporous film may take the form of an inverse-opal pattern and/or any other suitable structured nanocomponents, such as disclosed in co-pending U.S. patent application Ser. No. 12/777,748, filed May 11, 2010, and entitled “Composite Electron Conductor For Use In Photovoltaic Devices”, which is incorporated herein by reference.

A quantum dot layer 16 is shown electrically coupled to or otherwise disposed on electron conductor layer 14. In at least some embodiments, quantum dot layer 16 may be disposed over and “fill in” the structured pattern or array of electron conductor layer 14 when so provided. For example, in embodiments where electron conductor layer 14 is a mesoporous film, quantum dot layer 16 may be deposited onto one or more surfaces (e.g., along the inner surfaces) of the mesoporous film.

An electrolyte 18 may be electrically coupled to, and in some cases, disposed on or adjacent to quantum dot layer 16. Solar cell 10 may also include a second electrode 20 (e.g., a cathode or positive electrode) that is electrically coupled to one or more of electrolyte 18 and/or the quantum dot layer 16. Electrode (cathode) 20 may include a substrate or base 22 having a coating 24 thereon. In at least some embodiments, coating 24 may include a sulfur containing compound.

Substrate/electrode 12 may be made from a number of different materials including polymers, glass, and/or transparent materials. For example, substrate/electrode 12 may include polyethylene terephthalate, polyimide, low-iron glass, fluorine-doped tin oxide, indium tin oxide, Al-doped zinc oxide, transparent conductive oxide coated glass, any other suitable conductive inorganic element(s) or compound(s), conductive polymer(s), and/or other electrically conductive materials, combinations thereof, or any other suitable materials as desired.

Electron conductor layer 14, when provided, may be formed of any suitable material or material combination. In some cases, electron conductor layer 14 may be an n-type electron conductor. The electron conductor layer 14 may be metallic, and may include, for example, TiO₂ and/or ZnO. In some cases, electron conductor layer 14 may be an electrically conducting polymer, such as a polymer that has been doped to be electrically conducting or to improve its electrical conductivity.

As indicated above, in at least some embodiments, electron conductor layer 14 may be formed or otherwise include a structured pattern or array of, for example, nanoparticles. This may include screen printing electron conductor layer 14 on electrode 12 (and may or may not include disposing a compact TiO₂ blocking layer on electrode 12 prior to screen printing to prevent unwanted charge transfer). In at least some embodiments, electron conductor layer 14 may include a plurality of nanoparticles such as nanospheres or the like with relatively large average outer particle dimensions (e.g. diameters). In one illustrative embodiment, the electron conductor layer 14 of solar cell 10 may include TiO₂ nanoparticles with an average particle outer dimension (e.g. diameter) of about 10-300 nanometers, 25-100 nanometers, 25-45 nanometers, about 30-40 nanometers, or about 37 nanometers. When so configured, electron conductor layer 14 may allow for easier infiltration of quantum dot layer 16 onto electron conductor layer 14, and/or may reduced interfacial area with electrolyte 18, which may reduce electron-hole recombination and improve the energy conversion efficiency of solar cell 10.

In some embodiments, quantum dot layer 16 may include one quantum dot or a plurality of quantum dots. Quantum dots are typically very small semiconductors, having dimensions in the nanometer range. Because of their small size, quantum dots may exhibit quantum behavior that is distinct from what would otherwise be expected from a larger sample of the material. In some cases, quantum dots may be considered as being crystals composed of materials from Groups II-VI, III-V, or IV-VI materials. The quantum dots employed herein may be formed using any appropriate technique. Examples of specific pairs of materials for forming quantum dots include, but are not limited to, MgO, MgS, MgSe, MgTe, CaO, CaS, CaSe, CaTe, SrO, SrS, SrSe, SrTe, BaO, BaS, BaSe, BaTe, ZnO, ZnS, ZnSe, ZnTe, CdO, CdS, CdSe, CdTe, HgO, HgS, HgSe, HgTe, Al₂O₃, AI₂S₃, Al₂Se₃, Al₂Te₃, Ga₂O₃, Ga₂S₃, Ga₂Se₃, Ga₂Te₃, In₂O₃, In₂S₃, In₂Se₃, In₂Te₃, SiO₂, GeO₂, SnO₂, SnS, SnSe, SnTe, PbO, PbO₂, PbS, PbSe, PbTe, AlN, AlP, AlAs, AlSb, GaN, GaP, GaAs, GaSb, InN, InP, InAs and InSb.

In some embodiments, solar cell 10 may include a bifunctional ligand layer (not shown) that may help couple quantum dot layer 16 with electron conductor layer 14. At least some of the bifunctional ligands within the bifunctional ligand layer may be considered as including electron conductor anchors that may bond to electron conductor layer 14, and quantum dot anchors that may bond to individual quantum dots within quantum dot layer 16. A wide variety of bifunctional ligand layers are contemplated for use with the solar cells disclosed herein.

In some instances, electrolyte 18 may include a polysulfide electrolyte. The electrolyte 18 may include, for example, sulfur-based materials or electrolytes, sulfur-based electrolytic gels, ionic liquids, spiro-OMeTAD (2,20,7,70-tetrakis-(N,N-di-p-methoxyphenylamine)9,90-spirobifluorene), poly-3-hexylthiophen (P3HT), and/or the like. It is contemplated that forming such an electrolyte 18 may include providing a material (e.g., a sulfur-based material in liquid form) for forming electrolyte 18. A mixture of, for example, de-ionized water and a low surface tension solvent (e.g., methanol) may be used as a solvent for the electrolyte 18. In one specific example, the electrolyte 18 may include a sulfur-based liquid hole conductor material mixed in a low surface tension solvent, where the low surface tension solvent is a mixture that includes water and methanol. The low surface tension solvent may have a better affinity for the electron conductor layer 14 (e.g., TiO₂), which may help inhibit adsorption of H₂O on the TiO₂ surface, and may reduce electron-hole recombination and improve the overall efficiency of solar cell 10.

In at least some embodiments, the electrolyte 18 may be enhanced by the addition of an electrolytic salt. For example, an electrolytic salt (e.g., KCl, NaF, etc.) may be added to the electrolyte 18 material as an additive during manufacture. It is believed that the addition of such an electrolytic salt may reduce the internal electrical resistance of the electrolyte 18, and may improve the overall efficiency of solar cell 10. Electrolyte 18 may be considered as being electrically coupled to quantum dot layer 16. In some cases, two layers may be considered as being electrically coupled if one or more molecules or other moieties within one layer are bonded or otherwise secured to one or more molecules within another layer. In some instances, coupling infers the potential passage of electrons from one layer to the next.

In some embodiments, electrolyte 18 may include a hole conductor material and/or a hole conductor layer. Alternatively, a hole conductor layer may be used in lieu of electrolyte 18. The hole conductor layer may include a conductive polymer, but this is not required. In some cases, the conductive polymer may include a monomer that has an alkyl chain that terminates in a second quantum dot anchor. The conductive polymer may, for example, be or otherwise include a polythiophene that is functionalized with a moiety that bonds to quantum dots. In some cases, the polythiophene may be functionalized with a thio or thioether moiety.

An illustrative but non-limiting example of a suitable conductive polymer has

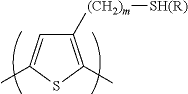

as a repeating unit, where R is absent or alkyl and m is an integer ranging from about 6 to about 12.

Another illustrative but non-limiting example of a suitable conductive polymer has

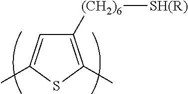

as a repeating unit, where R is absent or alkyl.

Another illustrative but non-limiting example of a suitable conductive polymer has

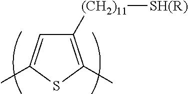

as a repeating unit, where R is absent or alkyl.

Another illustrative but non-limiting example of a suitable conductive polymer has

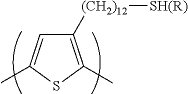

as a repeating unit, where R is absent or alkyl. These are just examples.

Substrate 22 (and/or electrode 20) may be made of materials similar to substrate 12. For example, substrate 22 may include a transparent conductive oxide coated glass such as a fluorine doped tin oxide glass, indium tin oxide glass, or the like. Of course, other materials are contemplated. In some embodiments, a metal underlayer (not shown) may be deposited on substrate 22 (e.g., prior to disposing coating 24 on substrate 22), which may improve conductivity.

In some instances, the cathode 20 of the solar cell 10 may include a coating 24 that is deposited on or otherwise electrically coupled to a substrate 22, but this is not required. The cathode 20 may include a sulfur-containing compound, which may be electrically coupled to the electrolyte 18 and/or the quantum dot layer 16. In at least some embodiments, the sulfur-containing compound may include, for example, CuS, Cu₂S, CoS, CoS₂, Fe₃S₄, and the like, or any other suitable material. In some instances, coating 24 of the cathode 20 may include the sulfur containing compound. The form of coating 24 may vary. In at least some embodiments, coating 24 may include a sulfide material such as CuS, Cu₂S, CoS, CoS₂, Fe₃S₄, and the like, or any other suitable material. The use of a sulfur-based compound in the cathode 20 (e.g., rather than a platinum coating or a platinum electrode) may be less costly, may reduce polysulfide ions to sulfide ions more efficiently (which may increase the effective fill factor), and may have less of a propensity for catalyzing unwanted “side” reactions (e.g., oxidation of electrolyte 18).

The process for disposing the coating 24 on the substrate 22 of the cathode 20 may include any suitable process. For example, a first aqueous solution (e.g., about 50 ml or so) may be provided that includes a first precursor material. In some embodiments, the first aqueous solution may be CoCl₂. The concentration of the first aqueous solution may vary and may be any suitable concentration (e.g., about 0.001 to 0.01 M). The substrate 22 may be immersed (e.g., vertically) in the first aqueous solution for a suitable time period (e.g., about 15 minutes or so) and at a suitable temperature (e.g., about 50-70° C. or so). A second aqueous solution (e.g., about 1.5 to 15 ml or so) including a second precursor material may be introduced slowly (e.g., which may also include stirring and/or heating) into the first aqueous solution to form coating 24 and deposit coating 24 onto cathode substrate 22. The second aqueous solution may include Na₂S at any suitable concentration (e.g., about 0.05 M). If heat and stirring is utilized, heating may occur over any suitable time period (e.g., about 2-6 hours or so) and at temperatures in the range of about 50-70° C. Once formed on the cathode substrate 22, coating 24 may be rinsed (e.g., with deionized water and/or ethanol), dried (e.g., with N₂), and annealed (e.g., in air at 300° C. for 1 hour; 1K/min).

In some instances, a solar cell may be assembled by growing nanoparticles of n-type semiconducting titanium dioxide (TiO₂) on a glass substrate, optionally followed by a sintering process. Next, quantum dots and an electrolyte 18 may be synthesized. In some cases, the solar cell 10 may be assembled by combining the individual components in a one-pot synthesis, but this is not required. In one example, a method of manufacturing a solar cell 10 may include providing electron conductor layer 14, electrically coupling quantum dot layer 16 to electron conductor layer 14, electrically coupling electrolyte 18 to quantum dot layer 16, and electrically coupling electrode 20 to one or more of electrolyte 18 and/or quantum dot layer 16. In other example embodiments, electrode (anode) 12 and electrode (cathode) 20 may be assembled together using a hot-melt ring, and an electrolyte solution 18 may be injected between electrodes 12/20. As disclosed above, the electron conductor layer 14 may include TiO₂ or other particles with an average particle outer dimension (e.g. diameter) of about 10-300 nanometers, 25-100 nanometers, 25-45 nanometers, about 30-40 nanometers, or about 37 nanometers. Alternatively, or in addition, the electrolyte solution 18 may include an electrolytic salt and/or a low surface tension solvent, if desired.

### EXAMPLES

The disclosure may be further clarified by reference to the following examples, which serve to exemplify some illustrative features, and are not meant to be limiting in any way.

### Example 1

A number of sample electrodes (cathodes) 20 were formed. The process for forming the electrodes included coating a sulfur-compound 24 on a substrate 22. The process included providing 50 ml of a 0.005M, 0.001M, or 0.01M CoCl₂ solution. A substrate (e.g., indium tin oxide glass) was immersed in the CoCl₂ solution. About 1.5 to 15 ml of 0.05 M aqueous solution of Na₂S was added slowly to the CoCl₂ solution while heating to a temperature between about 50-70° C. over a time period of about 2-6 hours. This deposited a CoS coating 24 onto a substrate 22. The particular parameters utilized to make various sample cathode electrodes 20 are listed in Table 1.

TABLE 1
Parameters used to make sample coated electrodes

| | Concentration of | Immersion Time | Deposition |
|---|---|---|---|
| Sample | CoCl₂ (M) | (hours) | Temperature (° C.) |
| A | 0.005 | 6 | 60 |
| B | 0.005 | 2 | 60 |
| C | 0.001 | 2 | 60 |
| D | 0.01 | 2 | 60 |
| E | 0.001 | 2 | 50 |
| F | 0.001 | 2 | 70 |
| G | 0.005 | 4 | 60 |
| H | 0.005 | 2 | 60 |

### Example 2

Some of the example electrodes formed in Example 1 were tested for surface species binding energies using X-ray Photoelectron Spectroscopy (XPS). The results are presented in Table 2.

TABLE 2
Surface species binding energy for sample electrodes

| Sample | Co/eV | S/eV | Co/S (mol/mol) |
|---|---|---|---|
| A | 781.0 | 169.0 | 9.1/1.3 |
| C | 781.2 | 169.0 | 6.8/1.2 |
| D | 781.6 | 168.6 | 5.1/1.0 |
| E | 781.4 | 168.8 | 8.5/1.3 |
| F | 781.0 | 168.6 | 6.2/1.1 |
| G | 781.2 | 168.8 | 8.5/4.2 |
| H | 781.4 | 169.0 | 13.1/2.4 |

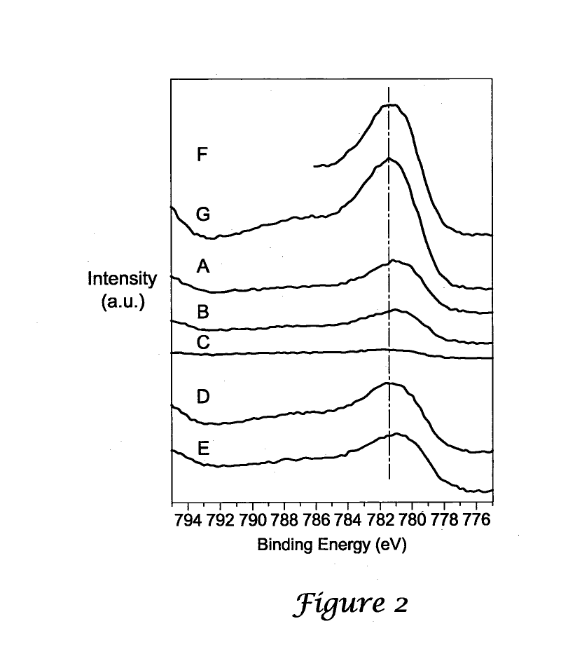

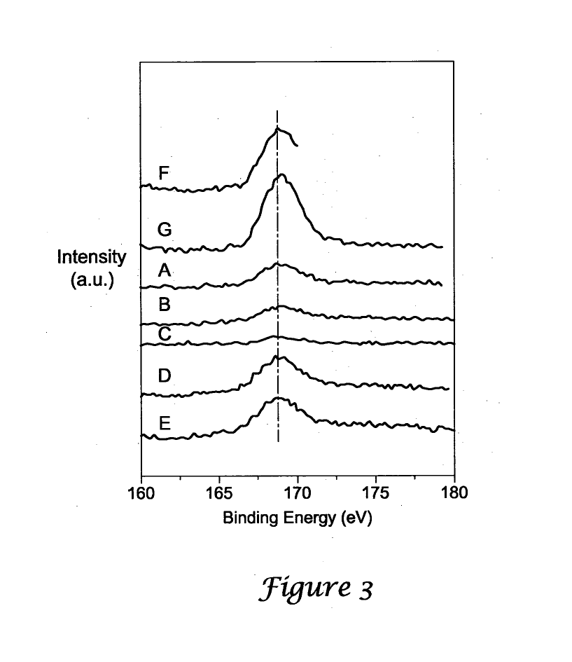

The 2p binding energy (eV) for Co is plotted versus intensity (absorption units (a.u.)) in FIG. 2. Similarly, the 2p binding energy (eV) for S is plotted versus intensity (a.u.) in FIG. 3. As can be seen, the surface species binding energy for Co is about 781 eV for all samples, and the surface species binding energy for S is about 169 eV for all samples. These values are consistent with the presence of Co and S, and are believed to be acceptable to produce a reliable solar cell, such as solar cell 10.

### Example 3

The stability of two example solar cells (designated Solar Cell A and Solar Cell B) with a

CoS coated electrode as described above was estimated by measuring a number of characteristics of the solar cells. Each solar cell was tested across an active area that was 0.7 cm². The results after day 1 are listed in Table 3.

TABLE 3
Stability estimate for sample solar cells after 1 day

| Solar | | J_{sc}² | | | | Rₛ⁵ (V_{oc}) | | Power |
|---|---|---|---|---|---|---|---|---|
| Cell | V_{oc}¹ | (mA/cm²) | FF³ | Efficiency | Rₛ⁴ (Ω) | (Ω) | Rₛₕ⁶ (Ω) | (mW) |
| A | 0.633872 | 9.41886 | 0.310165 | 1.85% | 65.39811 | 76.06347 | 289.3118 | 113.1 |
| B | 0.628667 | 9.041623 | 0.329684 | 1.87% | 69.73326 | 74.15084 | 418.9018 | 113.1 |

¹Open circuit voltage in volts
²Short circuit current density
³Fill factor
⁴Series resistance at 0.8 V
⁵Series resistance at V_{oc}
⁶Shunt resistance

The results after 6 days are listed in Table 4.

TABLE 4
Stability estimate for sample solar cells after 6 days

| Solar | | J_{sc}² | | | | Rₛ⁵ (V_{oc}) | | Power |
|---|---|---|---|---|---|---|---|---|
| Cell | V_{oc}¹ | (mA/cm²) | FF³ | Efficiency | Rₛ⁴ (Ω) | (Ω) | Rₛₕ⁶ (Ω) | (mW) |
| A | 0.632155 | 7.430385 | 0.538129 | 2.56% | 37.7465 | 47.84603 | 2075.773 | 111.5 |
| B | 0.623929 | 6.801707 | 0.552406 | 2.38% | 36.2476 | 46.9 | 2751.482 | 111.5 |

¹Open circuit voltage in volts
²Short circuit current density
³Fill factor
⁴Series resistance at 0.8 V
⁵Series resistance at V_{oc}
⁶Shunt resistance

The results after 9 days are listed in Table 5.

TABLE 5
Stability estimate for sample solar cells after 9 days

| Solar | | J_{sc}² | | | | Rₛ⁵ (V_{oc}) | | Power |
|---|---|---|---|---|---|---|---|---|
| Cell | V_{oc}¹ | (mA/cm²) | FF³ | Efficiency | Rₛ⁴ (Ω) | (Ω) | Rₛₕ⁶ (Ω) | (mW) |
| A | 0.629367 | 6.750364 | 0.546715 | 2.43% | 38.91686 | 50.18478 | 3344.904 | 108.2 |
| B | 0.626741 | 6.182224 | 0.559967 | 2.27% | 39.04646 | 51.27399 | 4643.151 | 108.2 |

¹Open circuit voltage in volts
²Short circuit current density
³Fill factor
⁴Series resistance at 0.8 V
⁵Series resistance at V_{oc}
⁶Shunt resistance

The results after 23 days are listed in Table 6.

TABLE 6
Stability estimate for sample solar cells after 23 days

| Solar | | J_{sc}² | | | | Rₛ⁵ (V_{oc}) | | Power |
|---|---|---|---|---|---|---|---|---|
| Cell | V_{oc}¹ | (mA/cm²) | FF³ | Efficiency | Rₛ⁴ (Ω) | (Ω) | Rₛₕ⁶ (Ω) | (mW) |
| A | 0.627268 | 5.460555 | 0.569342 | 2.03% | 38.72713 | 52.21949 | 4610.968 | 108.8 |
| B | 0.620836 | 4.738758 | 0.600096 | 1.84% | 37.25733 | 51.45507 | 5813.539 | 108.8 |

¹Open circuit voltage in volts
²Short circuit current density
³Fill factor
⁴Series resistance at 0.8 V
⁵Series resistance at V_{oc}
⁶Shunt resistance

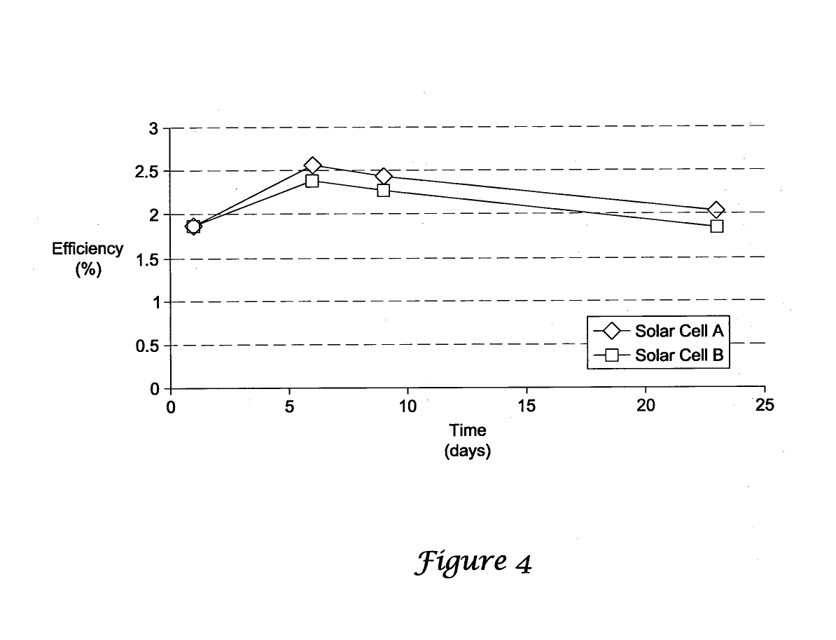

Efficiency is plotted versus time in FIG. 4. It can be seen, the sample solar cells A and B remain stable over an extended period of time (23 days).

This disclosure should not be considered limited to the particular examples described herein, but rather should be understood to cover all aspects of the disclosure as set out in the attached claims. Various modifications, equivalent processes, as well as numerous structures to which the disclosure can be applicable will be readily apparent to those of skill in the art upon review of the instant specification.

We claim:

1. A solar cell, comprising:
an anode;
a quantum dot layer electrically coupled to the anode;
an electrolyte disposed adjacent to the quantum dot layer; and
a cathode electrically coupled to one or more of the electrolyte and the quantum dot layer;
wherein the cathode includes a sulfur-containing compound.

2. The solar cell of claim 1, wherein the anode includes an electron conductor film that comprises ZnO, TiO₂, or both.

3. The solar cell of claim 1, wherein the anode includes an electron conductor film that comprises a plurality of nanoparticles having an average outer dimension that is between 10 and 300 nanometers.

4. The solar cell of claim 1, wherein the anode includes an electron conductor film that is a mesoporous film.

5. The solar cell of claim 4, wherein the quantum dot layer is deposited onto the mesoporous film.

6. The solar cell of claim 1, wherein the electrolyte is a polysulfide electrolyte.

7. The solar cell of claim 6, wherein the electrolyte is a polysulfide electrolyte that includes KCl, NaF, or both.

8. The solar cell of claim 7, wherein the electrolyte includes a low surface tension solvent.

9. The solar cell of claim 8, wherein the low surface tension solvent includes methanol.

10. The solar cell of claim 1, wherein the sulfur-containing compound of the cathode includes CuS.

11. The solar cell of claim 1, wherein the sulfur-containing compound of the cathode includes Cu₂S.

12. The solar cell of claim 1, wherein the sulfur-containing compound of the cathode includes CoS.

13. The solar cell of claim 1, wherein the sulfur-containing compound of the cathode includes CoS₂.

14. The solar cell of claim 1, wherein the sulfur-containing compound of the cathode includes Fe₃S₄.

15. A solar cell, comprising:
a photoanode including a mesoporous electron conductor film having particles with an average particle size of between 10-300 nanometers;
a quantum dot layer deposited onto the electron conductor film;
a polysulfide electrolyte disposed adjacent to the quantum dot layer; and
a sulfide compound coated counter-electrode electrically coupled to the polysulfide electrolyte, wherein the sulfide compound coated counter-electrode includes a coating material selected from the group comprising CuS, Cu₂S, CoS, CoS₂, and Fe₃S₄.

16. The solar cell of claim 15, wherein the mesoporous electron conductor film includes ZnO, TiO₂, or both.

17. The solar cell of claim 15, wherein the polysulfide electrolyte includes an electrolytic additive selected from the group comprising KCl and NaF.

18. The solar cell of claim 17, wherein the polysulfide electrolyte includes methanol.

19. The solar cell of claim 15, wherein the coating material of the sulfide compound coated counter-electrode is selected from the group comprising CuS and CoS.

20. A method of manufacturing a solar cell, comprising:
providing an anode including an electron conductor film;
depositing a quantum dot layer onto the electron conductor film;
disposing a polysulfide electrolyte adjacent to the quantum dot layer; and
electrically coupling a cathode to the polysulfide electrolyte, wherein the cathode includes a sulfur-containing compound.
